(19) United States
(12) Patent Application Publication
(10) Pub. No.: US 2020/0236804 A1
(43) Pub. Date: Jul. 23, 2020

(54) LAMINATE, MEMBER FOR ELECTRONIC DEVICES, AND ELECTRONIC DEVICE

(71) Applicant: LINTEC Corporation, Tokyo (JP)

(72) Inventors: Takumi FURUYA, Tokyo (JP); Satoshi NAGANAWA, Tokyo (JP); Wataru IWAYA, Tokyo (JP); Takehiro OHASHI, Tokyo (JP)

(73) Assignee: LINTEC Corporation, Tokyo (JP)

(21) Appl. No.: 16/305,480

(22) PCT Filed: May 11, 2017
(86) PCT No.: PCT/JP2017/017844

§ 371 Date: Nov. 29, 2018

(30) Foreign Application Priority Data
May 31, 2016 (JP) 2016-108540

(51) Int. Cl. H05K 5/06

(52) U.S. Cl. CPC H05K 5/065; H05K 5/0017

(57) ABSTRACT

The invention is a laminate comprising at least a base layer, a gas barrier layer, and a layer composed of a cured product of an energy-curable resin, wherein:
the gas barrier layer is laminated directly or via another layer on one side of the base layer; and
the layer composed of the cured product of the energy-curable resin is laminated directly or via another layer on a side opposite to the gas barrier layer of the base layer.

According to the present invention, there are provided a laminate excellent in gas barrier properties and unlike to cause a curl and a thermal contraction even when a thermal history is given so as to be suitably applicable to a sticking process to electronic devices, a member for electronic devices composed of the laminate, and an electronic device equipped with the member for electronic devices.

### TECHNICAL FIELD

The present invention relates to a laminate excellent in gas barrier properties and unlike to cause a curl and a thermal contraction even when a thermal history is given so as to suitably be applicable to a sticking process for electronic devices, a member for electronic devices composed of the laminate, and an electronic device equipped with the member for electronic devices.

### BACKGROUND ART

Recently, to realize thin thickness, lightweight, flexible properties and the like of displays such as a liquid crystal display and an electroluminescence (EL) display, there is used a so-called gas barrier film configured by laminating a gas barrier layer on a transparent plastic film, in place of a glass plate, as a substrate having an electrode.

For example, in Patent Literature 1, there is described a gas barrier film in which a specific thin film having silicon oxide as a main component is formed at least on one side of a base.

Moreover, in this literature, there is also described using an optically isotropic base to obtain the gas barrier film to be used suitably for optical applications is obtained.

### CITATION LIST

### Patent Literature

Patent Literature 1: JP-A-8-224825

### SUMMARY OF INVENTION

### Technical Problem

As described in Patent Literature 1, gas barrier films formed by using an optically isotropic base have been used suitably as a material for manufacturing various kinds of displays and the like.

However, when the displays and the like are manufactured using a conventional gas barrier film, the gas barrier film may curl or contract by a heat treatment in a manufacturing process and, as the result, an intended product sometimes cannot be manufactured effectively.

The present invention has been achieved in consideration of an actual condition, and aims at providing a laminate excellent in gas barrier properties and unlike to cause a curl and a thermal contraction even when a thermal history is given so as to be suitably applicable to a sticking process for electronic devices, a member for electronic devices composed of the laminate, and an electronic device equipped with the member for electronic devices.

### Solution to Problem

To solve the above-described problem, the present inventors have intensively examined laminated films having a base layer and a gas barrier layer. As a result, there was found that a laminate excellent in gas barrier properties and unlike to cause a curl and a thermal contraction even when a thermal history was given so as to suitably be applicable to a sticking process for electronic devices, was obtained by forming a gas barrier layer on one side of the base layer and forming a layer composed of a cured product of an energy-curable resin on a side opposite to the gas barrier layer of the base layer, to thereby finish the present invention.

Thus, according to the present invention, there are provided following laminates of (1) to (11), a member for electronic devices of (12), and an electronic device of (13).

(1) The laminate having at least a base layer, a gas barrier layer, and a layer composed of the cured product of the energy-curable resin, wherein the gas barrier layer is laminated directly or via another layer on one side of the base layer, and the layer composed of the cured product of the energy-curable resin is laminated directly or via another layer on a side opposite to the gas barrier layer of the base layer.

(2) The laminate according to (1), wherein a thermal contraction percentage is 0.2% or less in a case where the laminate is heat-treated at 100° C. for 1 hour in conformity with JIS K7133.

(3) The laminate according to (1) or (2), wherein in a case where the laminate is cut out in a square shape of 100 mm in one side and heated at 150° C. for 1 hour, and subsequently the laminate is placed on a horizontal pedestal and heights of four apexes are measured, the average value thereof is 10 mm or less.

(4) The laminate according to any of (1) to (3), wherein an in-plane retardation Re(550) of the laminate is 100 nm or less.

(5) The laminate according to any of (1) to (4), wherein a water vapor transmission rate under an atmosphere of 40° C. in temperature and 90% in relative humidity is less than 5.0 g·m⁻²·day⁻¹.

(6) The laminate according to any of (1) to (5), wherein glass-transition temperature (Tg) of the cured product of the energy-curable resin is 100° C. or higher.

(7) The laminate according to any of (1) to (6), wherein the base layer is a polycarbonate film or a film of alicyclic hydrocarbon-based resin.

(8) The laminate according to any of (1) to (7), wherein the gas barrier layer is an inorganic vapor-deposited film.

(9) The laminate according to any of (1) to (7), wherein the gas barrier layer is one composed by modifying a surface of a layer containing a polymer compound.

(10) The laminate according to any of (1) to (9), wherein the energy-curable resin is an ultraviolet ray-curable resin.

(11) The laminate according to any of (1) to (10), wherein thickness of the layer composed of the cured product of the energy-curable resin is 100 nm or larger.

(12) A member for electronic devices composed of the laminate according to any of the (1) to (11).

(13) An electronic device equipped with the member for electronic devices according to the (12).

### Advantageous Effects of Invention

According to the present invention, there are provided a laminate excellent in gas barrier properties and unlike to cause a curl and a thermal contraction even when a thermal history is given so as to be suitably applicable to a sticking process to electronic devices, a member for electronic devices composed of the laminate, and an electronic device equipped with the member for electronic devices.

### DESCRIPTION OF EMBODIMENTS

Hereinafter, present invention will be classified into 1) laminate and 2) member for electronic devices and electronic device, and will be explained in detail.

1) Laminate

The laminate of the present invention is a laminate having at least a base layer, a gas barrier layer and a layer composed of a cured product of an energy-curable resin, in which the gas barrier layer is laminated directly or via another layer on one side of the base layer, and the layer composed of the cured product of the energy-curable resin is laminated directly or via another layer on a side opposite to the gas barrier layer of the base layer.

[Base Layer]

The base layer configuring the laminate of the present invention is not particularly limited only if it can support the gas barrier layer and the layer composed of the cured product of the energy-curable resin.

As the base layer, a resin film can be used.

Resin components of the resin film include polyimide, polyamide, polyamide-imide, polyphenylene ether, polyether ketone, polyether ether ketone, polyolefin, polyester, polycarbonate, polysulfone, polyethersulfone, polyphenylene sulfide, acrylic-based resins, cycloolefin-based polymers, aromatic-based polymers, and the like.

These resin components can be used in one kind alone, or in two or more kinds in combination.

In a case where the laminate of the present invention is to be used as a manufacturing material of displays, the use of an optically isotropic film is preferable as the base layer. As a consequence of the use of an optically isotropic film as the base layer, it becomes easy to obtain an optically isotropic laminate for use in a process as a display material.

In the present invention, “optically isotropic” in an optically isotropic film and an optically isotropic laminate means having low birefringent properties. An in-plane retardation Re(550) of an optically isotropic film used for forming the base layer is preferably 100 nm or less.

In the present invention, the in-plane retardation Re(550) is retardation (R) in a plane when measurement is performed by light of 550 nm in wavelength, and is calculated according to a formula (1) below.

R=(nx−ny)×d (I)

(nx is a refractive index along a slow axis (direction having the highest refractive index) in a film plane, ny is a refractive index in a direction perpendicular to the slow axis in the film plane, and d is average thickness of the film).

Optically isotropic films include a polycarbonate film, a polysulfone film, films of acrylic-based resins, films of alicyclic hydrocarbon-based resins, and the like. Among these, because of a fact that an optically isotropic laminate having a small thermal contraction percentage and the small in-plane retardation Re(550) can be easily obtained easily, a polycarbonate film or films of alicyclic hydrocarbon-based resins are preferable, and films of alicyclic hydrocarbon-based resins are more preferable.

Alicyclic hydrocarbon-based resins are polymers having a cyclic hydrocarbon group in a main chain. Alicyclic hydrocarbon-based resins are not particularly limited, and known one can be used. Examples of alicyclic hydrocarbon-based resins include monocyclic cycloolefin-based polymers, norbornene-based polymers, cyclic conjugated diene-based polymers, vinyl alicyclic hydrocarbon polymer, and hydrogenated products thereof, for example. Commercial products include APEL (ethylene-cycloolefin copolymer, manufactured by Mitsui Chemicals, Inc.), TOPAS (ethylene-cycloolefin copolymer, manufactured by Polyplastics Co., Ltd.), ARTON (norbornene-based polymer, manufactured by JSR Corporation), ZEONOR (norbornene-based polymer, manufactured by ZEON CORPORATION), and the like.

The resin film used as the base layer may contain various kinds of additives in a range that does not hinder the effect of the present invention. Additives include an ultraviolet absorber, an antistatic agent, a stabilizer, an oxidation inhibitor, a plasticizer, a lubricant, a coloring pigment, and the like. A content of these additives may suitably be determined in accordance with the purpose.

Thickness of the resin film used as the base layer is not particularly limited. Since a thinner laminate can easily be obtained, the thickness of the resin film is preferably 500 μm or less, and more preferably 10 to 300 μm.

The resin film to be used as the base layer can be obtained by preparing a resin composition containing a resin component and various additives if desired, and molding the same in a film shape. The molding method is not particularly limited, and known methods such as a casting method and a melt-extrusion method can be utilized.

[Gas Barrier Layer]

The gas barrier layer constituting the laminate of the present invention is a layer having a property of suppressing penetration of a gas such as oxygen and water vapor (gas barrier property), and is configured by being laminated directly or via another layer on one side of the base layer.

Gas barrier layers include inorganic vapor-deposited films, one obtained by modifying a surface of a layer containing a polymer compound (hereinafter, may be referred to as a “polymer layer”) (in this case, a gas barrier layer means not only a modified region but also “a polymer layer containing a modified region”), and the like.

The inorganic vapor-deposited films include vapor-deposited films of an inorganic compound or metal.

Raw materials of a vapor-deposited film of an inorganic compound include inorganic oxides such as silicon oxide, aluminum oxide, magnesium oxide, zinc oxide, indium oxide and tin oxide; inorganic nitrides such as silicon nitride, aluminum nitride and titanium nitride; inorganic carbides; inorganic sulfides; inorganic oxynitrides such as silicon oxynitride; inorganic oxycarbides; inorganic nitridecarbides; inorganic oxynitride carbides and the like.

Raw materials of a vapor-deposited film of metal include aluminum, magnesium, zinc, tin and the like.

These can be used in one kind alone, or in two or more kinds in combination.

Among these, from the viewpoint of a gas barrier property, an inorganic vapor-deposited film derived from an inorganic oxide, inorganic nitride or metal as a raw material is preferable, and from the viewpoint of transparency in addition, an inorganic vapor-deposited film derived from an inorganic oxide or inorganic nitride as a raw material is preferable.

Methods for forming an inorganic vapor-deposited film include PVD (physical vapor deposition) methods such as a vacuum deposition method, a sputtering method and an ion plating method, and CVD (chemical vapor deposition) methods such as a thermal CVD method, a plasma CVD method and a photo-CVD method.

Thickness of an inorganic vapor-deposited film depends on an inorganic compound or metal to be used but, from the viewpoint of a gas barrier property and handling property, lies preferably in a range of 50 to 300 nm, and more preferably in a range of 50 to 200 nm.

Polymer compounds to be used in a gas barrier layer configured by surface modification of a polymer layer include silicon-containing polymer compounds, polyimide, polyamide, polyamide-imide, polyphenylene ether, polyether ketone, polyether ether ketone, polyolefin, polyester, polycarbonate, polysulfone, polyethersulfone, polyphenylenesulfide, polyarylate, acrylic-based resins, alicyclic hydrocarbon-based resins, aromatic polymers, and the like.

These polymer compounds can be used in one kind alone, or in two or more kinds in combination.

The polymer layer may contain other components in addition to polymer compounds in a range that does not inhibit the purpose of the present invention. Other components include a curing agent, an aging inhibitor, a light stabilizer, a flame retardant, and the like.

The content of the polymer compound in the polymer layer is preferably not less than 50% by mass, and more preferably not less than 70% by mass, because a gas barrier layer more excellent in gas barrier properties can be formed.

Thickness of the polymer layer is not particularly limited, but is usually 20 nm to 50 μm, preferably 30 nm to 1 μm, and more preferably 40 nm to 500 nm.

The polymer layer can be formed, for example, by applying directly or via another layer a liquid obtained by dissolving or dispersing a polymer compound in an organic solvent onto a resin film to be the base layer by a known coating method, and drying the obtained coating film.

Organic solvents include aromatic hydrocarbon-based solvents such as benzene and toluene; ester-based solvents such as ethyl acetate and butyl acetate; ketone-based solvents such as acetone, methyl ethyl ketone and methyl isobutyl ketone; aliphatic hydrocarbon-based solvents such as n-pentane, n-hexane and n-heptane; alicyclic hydrocarbon-based solvents such as cyclopentane and cyclohexane; and the like.

These solvents can be used in one kind alone, or in two or more kinds in combination.

Application methods include a bar-coating method, a spin-coating method, a dipping method, a roll-coating method, a gravure-coating method, a knife-coating method, an air knife-coating method, a roll knife-coating method, a die-coating method, a screen printing method, a spray-coating method, a gravure offset method, and the like.

Drying methods of a coating film include conventionally known drying methods such as hot air drying, hot roll drying and infrared ray irradiation. Heating temperature is usually 80 to 150° C., and heating time is usually several tens of seconds to several tens of minutes.

Modifying methods of a polymer layer surface include an ion implantation treatment, a plasma treatment, an ultraviolet ray irradiation treatment, a heat treatment, and the like.

The ion implantation treatment is a method of implanting accelerated ions into a polymer layer to thereby modify the polymer layer surface, as described later.

The plasma treatment is a method of exposing a polymer layer in plasma to thereby modify the polymer layer surface. For example, the plasma treatment can be performed according to the method described in JP-A-2012-106421.

The ultraviolet ray irradiation treatment is a method of irradiating a polymer layer with ultraviolet rays to thereby modify the polymer layer surface. For example, an ultraviolet ray modifying treatment can be performed according to the method described in JP-A-2013-226757.

Among these gas barrier layers, one obtained by subjecting a layer containing a silicon-containing polymer compound to an ion implantation treatment is preferable, because of more excellent gas barrier properties.

Silicon-containing polymer compounds include polysilazane-based compounds, polycarbosilane-based compounds, polysilane-based compounds, polyorganosiloxane-based compounds, poly(disilanylenephenylene)-based compounds, poly(disilanyleneethynylene)-based compounds and the like, and polysilazane-based compounds are more preferable.

Polysilazane-based compounds are compounds having a repeating unit containing a —Si—N— bond (silazane bond) in a molecule. Specifically, compounds having a repeating unit represented by formula (1) are preferable.

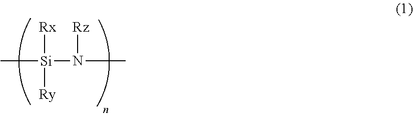

Number average molecular weight of a polysilazane-based compound to be used is not particularly limited, but is preferably 100 to 50,000.

In the formula (1), n represents an arbitrary natural number. Each of Rx, Ry and Rz independently represents a hydrogen atom, or a non-hydrolyzable group such as an unsubstituted or substituted alkyl group, an unsubstituted or substituted cycloalkyl group, an unsubstituted or substituted alkenyl group, an unsubstituted or substituted aryl group or an alkylsilyl group.

Alkyl groups of the unsubstituted or substituted alkyl group include alkyl groups having 1 to 10 carbon atoms such as a methyl group, an ethyl group, a n-propyl group, an isopropyl group, a n-butyl group, an isobutyl group, a sec-butyl group, a t-butyl group, a n-pentyl group, an isopentyl group, a neopentyl group, a n-hexyl group, a n-heptyl group and a n-octyl group, for example.

Cycloalkyl groups of the unsubstituted or substituted cycloalkyl group include cycloalkyl groups having 3 to 10 carbon atoms such as a cyclobutyl group, a cyclopentyl group, a cyclohexyl group and a cycloheptyl group.

Alkenyl groups of the unsubstituted or substituted alkenyl group include alkenyl groups having 2 to 10 carbon atoms such as a vinyl group, a 1-propenyl group, a 2-propenyl group, a 1-butenyl group, a 2-butenyl group and a 3-butenyl group.

Substituents of the alkyl group, cycloalkyl group and alkenyl group include a halogen atom such as a fluorine atom, a chlorine atom, a bromine atom and an iodine atom; a hydroxyl group; a thiol group; an epoxy group; a glycidoxy group; a (meth)acryloyloxy group; unsubstituted or substituted aryl groups such as a phenyl group, a 4-methylphenyl group and a 4-chlorophenyl group; and the like.

Aryl groups of the unsubstituted or substituted aryl group include aryl groups having 6 to 15 carbon atoms such as a phenyl group, a 1-naphthyl group and a 2-naphthyl group.

Substituents of the aryl group include a halogen atom such as a fluorine atom, a chlorine atom, a bromine atom and an iodine atom; an alkyl group having 1 to 6 carbon atoms such as a methyl group and an ethyl group; an alkoxy group having 1 to 6 carbon atoms such as a methoxy group and an ethoxy group; a nitro group; a cyano group; a hydroxyl group; a thiol group; an epoxy group; a glycidoxy group; a (meth)acryloyloxy group; an unsubstituted or substituted aryl group such as a phenyl group, a 4-methyl phenyl group and a 4-chlorophenyl group; and the like.

Alkylsilyl groups include a trimethylsilyl group, a triethylsilyl group, a triisopropylsilyl group, a tri-t-butylsilyl group, a methyldiethylsilyl group, a dimethylsilyl group, a diethylsilyl group, a methylsilyl group, an ethylsilyl group, and the like.

Among these, as each of Rx, Ry and Rz, a hydrogen atom, an alkyl group having 1 to 6 carbon atoms or a phenyl group is preferable, and a hydrogen atom is particularly preferable.

Polysilazane-based compounds having a repeating unit represented by the formula (1) may be either inorganic polysilazane in which all Rx, Ry and Rz are hydrogen atoms, or organic polysilazane in which at least one of Rx, Ry and Rz is not a hydrogen atom.

Moreover, in the present invention, a polysilazane-modified product may be used as a polysilazane-based compound. Examples of polysilazane-modified products include those described in JP-A-62-195024, JP-A-63-81122, JP-A-2-84437, JP-A-1-138108, JP-A-2-175726, JP-A-5-238827, JP-A-5-238827, JP-A-6-122852, JP-A-6-306329, JP-A-6-299118, JP-A-9-31333, JP-A-5-345826 and JP-A-4-63833, and the like.

Among these, from the viewpoint of easy availability and formability of an ion implantation layer having excellent gas barrier properties, perhydropolysilazane, in which all Rx, Ry and Rz are hydrogen atoms, is preferable as the polysilazane-based compound.

Moreover, as a polysilazane-based compound, commercial products available as a glass coating material and the like can be used as it is.

Polysilazane-based compounds can be used in one kind alone, or in two or more kinds in combination.

Ions to be implanted in a polymer layer include ions of rare gases such as argon, helium, neon, krypton and xenon; ions of fluorocarbon, hydrogen, nitrogen, oxygen, carbon dioxide, chlorine, fluorine and sulfur; ions of alkane-based gases such as methane and ethane; ions of alkene-based gases such as ethylene and propylene; ions of alkadiene-based gases such as pentadiene and butadiene; ions of alkyne-based gases such as acetylene; ions of aromatic hydrocarbon-based gases such as benzene and toluene; ions of cycloalkane-based gases such as cyclopropane; ions of cycloalkene-based gases such as cyclopentene; ions of metals; ions of organic silicon compounds; and the like.

These ions can be used in one kind alone, or in two or more kinds in combination.

Among these, ions of rare gases such as argon, helium, neon, krypton and xenon are preferable, because these ions can be implanted in an easier and simpler way to form a gas barrier layer having more excellent gas barrier properties.

An implantation amount of ions can be suitably determined in accordance with an intended purpose (necessary gas barrier properties, transparency, etc.) of a laminate, and the like.

Implanting methods of ions include a method of irradiation with ions accelerated by an electric field (ion beam), a method of implanting ions in plasma, and the like. Among these, the latter method of implanting ions in plasma (plasma ion implantation method) is preferable because an intended gas barrier layer can be formed in an easy and simple way.

A plasma ion implantation method can be performed, for example, by generating plasma under an atmosphere containing a plasma generation gas (the gas that generates ions to be implanted into the polymer layer) and applying a negative high voltage pulse to a polymer layer to thereby implant ions (positive ions) in the plasma into a surface part of the polymer layer. More specifically, the plasma ion implantation method can be performed by a method described in WO 2010/107018 brochure or the like.

Thickness of a region into which ions are to be implanted by ion implantation can be controlled by implantation conditions such as a kind of the ion, applied voltage and treatment time and may be determined in accordance with the thickness of a polymer layer, an intended purpose of a laminate and the like, but is usually 10 to 400 nm.

A fact that ions have been implanted can be confirmed by performing elemental analysis measurement in a position approximately 10 nm from the surface of the polymer layer using X-ray photoelectron spectroscopy (XPS).

The gas barrier layer configuring the laminate of the present invention is one laminated directly or via another layer on one side of the base layer.

In a case where a laminate has other layers between the base layer and the gas barrier layer, the other layers include a primer layer and the like. The primer layer is not particularly limited, and can be formed according to a known method.

[Layer Composed of Cured Product of Energy-Curable Resin]

The layer that configures the laminate of the present invention and is composed of the cured product of the energy-curable resin is a layer configured by curing the energy-curable resin, and is a layer laminated directly or via another layer on a side opposite to the gas barrier layer of the base layer (hereinafter, may be referred to as a “counter layer”).

As a consequence of the fact that the laminate of the present invention has the counter layer, a curl when a thermal history is given is suppressed.

The energy-curable resin means a curable resin composition in which a curing reaction starts by performing irradiation of an energy ray such as electron beam or ultraviolet ray, or performing heating, to cause conversion to a cured product. The energy-curable resin usually contains a polymerizable compound as a main component.

The polymerizable compound is a compound having an energy-polymerizable functional group. Examples of energy-polymerizable functional groups include ethylenically unsaturated groups such as a (meth)acryloyl group, a vinyl group, an allyl group and a styryl group. Among these, because of high reactivity, a (meth)acryloyl group is preferable. Meanwhile, in the present description, a “(meth)acryloyl group” means an acryloyl group or a methacryloyl group.

Polymerizable compounds having a (meth)acryloyl group include polyfunctional acrylate-based compounds. Polyfunctional acrylate-based compounds mean acrylic acid ester compounds or methacrylic acid ester compounds having two or more unsaturated bonds that take part in a polymerization reaction.

Polyfunctional acrylate-based compounds include bifunctional acrylate-based compounds such as tricyclodecane dimethanol di(meth)acrylate, 1,4-butanediol di(meth)acrylate, 1,6-hexanediol di(meth)acrylate, neopentyl glycol di(meth)acrylate, polyethylene glycol di(meth)acrylate, neopentyl glycol adipate di(meth)acrylate, hydroxy pivalic acid neopentyl glycol di(meth)acrylate, dicyclopentanyl di(meth)acrylate, caprolactone-modified dicyclopentenyl di(meth)acrylate, ethylene oxide-modified phosphoric acid di(meth)acrylate, di(acryloyloxyethyl)isocyanurate and allylated cyclohexyl di(meth)acrylate; trifunctional acrylate-based compounds such as trimethylolpropane tri(meth)acrylate, dipentaerythritol tri(meth)acrylate, propionic acid-modified dipentaerythritol tri(meth)acrylate, pentaerythritol tri(meth)acrylate, propylene oxide-modified trimethylolpropane tri(meth)acrylate and tris(2-acryloyloxyethyl)isocyanurate; tetrafunctional acrylate-based compounds such as diglycerin tetra(meth)acrylate and pentaerythritol tetra(meth)acrylate; pentafunctional acrylate-based compounds such as propionic acid-modified dipentaerythritol penta(meth)acrylate; hexafunctional acrylate-based compounds such as dipentaerythritol hexa(meth)acrylate and caprolactone-modified dipentaerythritol hexa(meth)acrylate; and the like.

These polyfunctional acrylate-based compounds can be used in one kind alone, or in two or more kinds in combination.

The energy-curable resin may contain an oligomer. Such oligomers include polyester acrylate-based oligomers, epoxy acrylate-based oligomers, urethane acrylate-based oligomers, polyol acrylate-based oligomers, and the like.

The energy-curable resin may contain a polymerization initiator such as a photopolymerization initiator or a thermal polymerization initiator.

Photopolymerization initiators include ketone-based photopolymerization initiators such as 2,2-dimethoxy-1,2-diphenylethane-1-one and 1-hydroxycyclohexyl phenyl ketone; phosphorous-based photopolymerization initiators such as 2,4,6-trimethylbenzoyl diphenylphosphine oxide, bis(2,4,6-trimethylbenzoyl)phenylphosphine oxide, ethyl(2,4,6-trimethylbenzoyl) phenylphosphinate and bis(2,6-dimethoxybenzoyl)-2,4,4-trimethyl-pentylphosphine oxide; titanocene-based photopolymerization initiators such as bis(η5-2,4-cyclopentadien-1-yl)-bis[2,6-difluoro-3-(1H-pyrrole-1-yl)phenyl]titanium; oxime ester-based photopolymerization initiators; benzophenone-based photopolymerization initiators such as benzophenone, p-chlorobenzophenone and 4,4′-(diethylamino)benzophenone; thioxantone-based photopolymerization initiators such as thioxantone; amine-based photopolymerization initiators such as triisopropanolamine; and the like. These can be used in one kind alone, or in two or more kinds in combination.

Thermal polymerization initiators include hydrogen peroxide; peroxodisulfates such as ammonium peroxodisulfate, sodium peroxodisulfate and potassium peroxodisulfate; azo-based compounds such as 2,2′-azobis(2-amidinopropane) dihydrochloride, 4,4′-azobis(4-cyanovaleric acid), 2,2′-azobisisobutyronitrile and 2,2′-azobis(4-methoxy-2,4-dimethylvaleronitrile); organic peroxides such as benzoyl peroxide, lauroyl peroxide, peracetic acid, persuccinic acid, di-t-butyl peroxide, t-butyl hydroperoxide and cumene hydroperoxide; and the like. These can be used in one kind alone, or in two or more kinds in combination.

When the energy-curable resin contains a polymerization initiator, the content thereof lies usually in a range of 0.01 to 20 parts by mass relative to 100 parts by mass of a polymerizable compound.

The energy-curable resin may contain a polyisocyanate-based crosslinking agent. The polyisocyanate-based crosslinking agent is not particularly limited, and a compound having two or more isocyanate groups in a molecule is used. Polyisocyanate-based crosslinking agents include aromatic polyisocyanates such as tolylene diisocyanate, diphenylmethane diisocyanate and xylylene diisocyanate; aliphatic polyisocyanates such as hexamethylene diisocyanate; alicyclic polyisocyanates such as isophorone diisocyanate and hydrogenated diphenylmethane diisocyanate; and biuret products and isocyanurate products thereof, and, additionally, adduct products that are reaction products with a low molecular weight active hydrogen-containing compounds such as ethylene glycol, propylene glycol, neopentyl glycol, trimethylolpropane and castor oil; and the like. These can be used in one kind alone, or in two or more kinds in combination.

When the energy-curable resin contains a polyisocyanate-based crosslinking agent, the content thereof is usually 1 to 10 parts by mass, and preferably 2 to 8 parts by mass relative to 100 parts by mass of a polymerizable compound.

As the energy-curable resins, resins curable by ultraviolet ray irradiation (ultraviolet ray-curable resins) are preferable. The use of an ultraviolet ray-curable resin makes it possible to form effectively a layer composed of the cured product of the energy-curable resin.

The counter layer configuring the laminate of the present invention can be formed by applying directly or via another layer a coating liquid containing the energy-curable resin and a solvent onto a side opposite to the gas barrier layer of the base layer by a known application method, drying if needed an obtained coating film and, subsequently, curing the coating film.

Solvents include aliphatic hydrocarbon-based solvents such as n-hexane and n-heptane; aromatic hydrocarbon-based solvents such as toluene and xylene; halogenated hydrocarbon-based solvents such as dichloromethane, ethylene chloride, chloroform, carbon tetrachloride, 1,2-dichloroethane and monochlorobenzene; alcohol-based solvents such as methanol, ethanol, propanol, butanol and propylene glycol monomethyl ether; ketone-based solvents such as acetone, methyl ethyl ketone, 2-pentanone, isophorone and cyclohexanone; ester-based solvents such as ethyl acetate and butyl acetate; cellosolve-based solvents such as ethyl cellosolve; ether-based solvents such as 1,3-dioxolan; and the like.

As the application method of a coating liquid, usual wet coating method can be used. For example, there are included a dipping method, roll coating, gravure coating, knife coating, air knife coating, roll knife coating, die coating, a screen printing method, spray coating, a gravure offset method, and the like.

Methods for drying a coating film include conventionally known drying methods such as hot air drying, hot roll drying and infrared ray irradiation.

A method for curing a coating film is not particularly limited, and a known method can appropriately be selected in accordance with properties of the energy-curable resin.

For example, in a case where the energy-curable resin is one curable by receiving an active energy ray, a coating film can be cured by irradiating the coating film with active energy ray using a high-pressure mercury lamp, an electrodeless lamp, a xenon lamp or the like.

The wavelength of the active energy ray is preferably 200 to 400 nm, and more preferably 350 to 400 nm. An irradiation dose is usually in a range of 50 to 1000 mW/cm² in illuminance, and 50 to 5000 mJ/cm² in light quantity, preferably 1000 to 5000 mJ/cm². Irradiation time is usually 0.1 to 1000 sec, preferably 1 to 500 sec, and more preferably 10 to 100 sec. To fulfill the above-described light quantity considering a heat load in a light irradiation process, repeating irradiation is allowed.

In a case where the energy-curable resin is one curable by heating, a coating film can be cured by heating the coating film to a temperature at which a curing reaction progresses.

Thickness of the counter layer is not particularly limited, and may be determined appropriately in accordance with an intended purpose and the like of the laminate. The thickness of the counter layer is usually 100 nm or more, and preferably 0.10 to 10 μm.

(Laminate)

The laminate of the present invention can be manufactured by forming the gas barrier layer, the counter layer and the like on the base layer according to the above-described method. Formation order of the gas barrier layer and the counter layer is not particularly limited, and the gas barrier layer may be formed first, or the counter layer may be formed first.

Thickness of the laminate of the present invention is not particularly limited, and is preferably 5 to 500 μm, more preferably 10 to 300 μm, but particularly preferably 20 to 200 μm.

The laminate of the present invention is excellent in gas barrier properties.

A water vapor transmission rate of the laminate of the present invention is preferably less than 5.0 g·m⁻²·day⁻¹, and more preferably less than 0.5 g·m⁻²·day⁻¹ under an atmosphere of 40° C. in temperature and 90% in relative humidity. A lower limit is not particularly present and a smaller value is more preferable, but is usually 1×10⁻⁶ g·m⁻²·day⁻¹ or more.

The water vapor transmission rate can be measured by a method described in Example.

The laminate of the present invention is preferably excellent in transparency. The total luminous transmittance of the laminate measured in conformity with JIS K 7361-1 is preferably 85% or more.

The laminate of the present invention is preferably excellent in optical isotropy. The in-plane retardation Re(550) of the laminate of the present invention is preferably 100 nm or less, and more preferably 10 nm or less.

The laminate of the present invention is excellent in heat resistance.

When the curl is evaluated according to a method described in Example, an average value of heights of four apexes is preferably 10 mm or less.

Moreover, when a thermal contraction percentage is measured according to a method described in Examples, the thermal contraction percentage is preferably 0.20% or less.

2) Member for Electronic Devices and Electronic Device

The member for electronic devices of the present invention is characterized by being composed of the laminate of the present invention having excellent gas barrier properties. Accordingly, the member for electronic devices of the present invention also has excellent gas barrier properties and, therefore, can prevent deterioration of elements due to gases such as water vapor. Furthermore, even when a thermal history is given, the curl and the thermal contraction are unlikely to occur and, therefore, intended electronic devices can effectively be manufactured.

Moreover, the member for electronic devices composed of the laminate excellent in optical isotropy is suitable as a member for the displays such as a liquid crystal display and an EL display; and the like.

The electronic device of the present invention is equipped with the member for electronic devices of the present invention. Specific examples include the liquid crystal display, an organic EL display, an inorganic EL display, electronic paper, a solar cell and the like.

The electronic device of the present invention is equipped with the member for electronic devices composed of the laminate of the present invention and, therefore, is unlikely to cause failures due to penetration of water vapor and the like and is excellent in visibility.

### EXAMPLES

Hereinafter, the present invention is explained in more detail with reference to Examples. However, the present invention is not limited to Examples below.

In each example, “part” and “%” are based on mass, unless otherwise noted.

[Glass-Transition Temperature (Tg) of Layer Composed of Cured Product of Energy-Curable Resin]

Glass-transition temperature (Tg) of a layer composed of a cured product of an energy-curable resin, the layer configuring the laminate obtained in Examples or Comparative Examples, was measured in conformity with JIS K 7121 at a temperature increasing rate of 20° C./min using a differential scanning calorimeter (product name: “DSC Q2000” manufactured by TA Instruments Japan Inc.).

[Evaluation of Gas Barrier Properties of Laminate]

For a laminate obtained in Examples or Comparative Examples, a water vapor transmission rate (g·m⁻²·day⁻¹) was measured under conditions of 40° C. and 90% in relative humidity using “AQUATRAN” manufactured by MOCON Inc.

[Evaluation of Transparency of Laminate]

For a laminate obtained in Examples or Comparative Examples, the total luminous transmission rate was measured in conformity with JIS K7361.

[Evaluation of Optical Isotropy of Laminate]

For a laminate obtained in Examples or Comparative Examples, an in-plane retardation Re(550) was measured using “KOBRA-WR” manufactured by Oji Scientific Instruments.

[Evaluation of Curl of Laminate after Heating]

A laminate obtained in Examples or Comparative Examples was cut out in a square shape of 100 mm in one side to thereby give a test piece. The test piece was heated at 150° C. for 1 hour, which was subsequently placed of a horizontal pedestal to measure heights of four apexes, and an average value thereof was calculated.

[Evaluation of Thermal Contraction Percentage of Laminate]

For a laminate obtained in Examples or Comparative Examples, a thermal contraction percentage when a heat treatment at 100° C. for 1 hour was performed was measured in conformity with JIS K7133.

[Evaluation of Sticking]

A laminate obtained in Examples or Comparative Examples was cut out in ISO A4 size, which was heat-treated at 100° C. for 1 hour in conformity with JIS K7133 and then set as an evaluation sample. The evaluation sample was stuck to a glass substrate in ISO A4 size with a sticking machine (HAL-320, manufactured by SANKYO CO., LTD.), and cases where displacement between the evaluation sample and the glass substrate was 5 mm or less and crease or fold did not present were determined as good, and cases where displacement exceeded 5 mm or crease or fold was present were determined as no-good.

### Example 1

Onto a cycloolefin copolymer film manufactured by Gunze Limited (“F1-ISO-80”, thickness 80 μm, in-plane retardation Re(550) 2 nm), a coating agent having perhydropolysilazane as a main component (“AQUAMICA NL110-20”, solvent: xylene, concentration: 10%, manufactured by AZ Electronic Materials) was applied by a spin coating method, and an obtained coating film was dried at 120° C. for 2 min to form a polysilazane layer of 150 nm in thickness.

For the obtained polysilazane layer, plasma ion implantation was performed under following conditions using a plasma ion implantation apparatus (RF power source: “RF56000” manufactured by JEOL Ltd., high voltage pulse power source: “PV-3-HSHV-0835” manufactured by Kurita Manufacturing Co., Ltd.) to thereby form a gas barrier layer.

Plasma generation gas: Ar

Gas flow rate: 100 seem

Duty ratio: 0.5%

Applied voltage: −6 kV

RF source: frequency 13.56 MHz, applied power 1000 W

Chamber inner pressure: 0.2 Pa

Pulse width: 5 μsec

Processing time (ion implantation time): 200 sec

Onto a surface of a side opposite to the gas barrier layer of the cycloolefin copolymer film, “OPSTAR Z7530” manufactured by JSR Corporation was applied with a Meyer bar, the obtained coating film was dried at 70° C. for 1 min, then the coating film was cured by UV irradiation to form a layer (layer composed of the cured product of the energy-curable resin, glass-transition temperature (Tg) was 300° C.) having thickness of 1 μm, and thus a laminate was obtained.

### Example 2

The procedure in Example 1 was repeated, except for using a polycarbonate film (“C110-80” manufactured by Teijin Limited, thickness: 80 μm, in-plane retardation Re(550): 6 nm) in place of the cycloolefin copolymer film to give a laminate.

### Example 3

The procedure in Example 1 was repeated, except for using a polyethylene terephthalate film (“COSMOSHINE A4300” manufactured by Toyobo Co., Ltd., thickness: 50 μm, in-plane retardation Re(550)>2000 nm) in place of the cycloolefin copolymer film to give a laminate.

### Comparative Example 1

In Example 1, the layer composed of the cured product of the energy-curable resin was not formed, to give a laminate composed of a base layer and the gas barrier layer.

### Comparative Example 2

In Example 2, the layer composed of the cured product of the energy-curable resin was not formed, to give a laminate composed of the base layer and the gas barrier layer.

### Comparative Example 3

In Example 3, the layer composed of the cured product of the energy-curable resin was not formed, to give a laminate composed of the base layer and the gas barrier layer.

For laminates obtained in Examples 1 to 3 and Comparative Examples 1 to 3, above-described evaluation tests were performed. Results are shown in Table 1.

TABLE 1

| | Gas barrier | Transparency | | Curl evaluation of | | |
|---|---|---|---|---|---|---|
| | property | evaluation | Optical isotropy | laminate after | Thermal | |
| | evaluation | Total luminous | evaluation | heating | contraction | |
| | Water vapor | transmittance | In-plane retardation | (average of heights | percentage | Sticking |
| | transmission rate | (measurement) | (measurement) | of apexes) | (measurement) | evaluation |
| | (g · m⁻² · day⁻¹) | (evaluation) | (evaluation) | (evaluation) | (evaluation) | (evaluation) |
| Example 1 | 0.012 | 91% | 2 nm | 0 mm | 0.09% | Good |
| Example 2 | 0.013 | 88% | 6 nm | 1 mm | 0.03% | Good |
| Example 3 | 0.012 | 90% | >2000 nm | 5 mm | 0.18% | Good |
| Comparative | 0.015 | 91% | 3 nm | 25 mm | 0.05% | No-good |
| Example 1 | | | | | | |
| Comparative | 0.014 | 89% | 6 nm | 19 mm | 0.05% | No-good |
| Example 2 | | | | | | |
| Comparative | 0.018 | 90% | >2000 nm | 35 mm | 0.22% | No-good |
| Example 3 | | | | | | |

From Table 1, the following is found.

The laminates in Examples 1 to 3 have the layer composed of the cured product of the energy-curable resin. In these laminates, when sticking to a device, the sticking can be performed without displacement, and furthermore without a crease or fold.

In particular, laminates obtained in Examples 1 and 2 are excellent in gas barrier properties, transparency and optical isotropy and are unlikely to cause the curl or thermal contraction after heating, and thus are suitable as a manufacturing material for displays.

1-13. (canceled)

14. A laminate comprising at least a base layer, a gas barrier layer, and a layer composed of a cured product of an energy-curable resin, wherein:
the gas barrier layer is laminated directly or via another layer on one side of the base layer; and
the layer composed of the cured product of the energy-curable resin is laminated directly or via another layer on a side opposite to the gas barrier layer of the base layer.

15. The laminate according to claim 14, wherein a thermal contraction percentage is 0.2% or less in a case where the laminate is heat-treated at 100° C. for 1 hour in conformity with JIS K7133.

16. The laminate according to claim 14, wherein in a case where the laminate is cut out in a square shape of 100 mm in one side and heated at 150° C. for 1 hour, and subsequently the laminate is placed on a horizontal pedestal and heights of four apexes are measured, the average value thereof is 10 mm or less.

17. The laminate according to claim 14, wherein an in-plane retardation Re(550) of the laminate is 100 nm or less.

18. The laminate according to claim 14, wherein a water vapor transmission rate under an atmosphere of 40° C. in temperature and 90% in relative humidity is less than 5.0 g·m⁻²·day⁻¹.

19. The laminate according to claim 14, wherein glass-transition temperature (Tg) of the cured product of the energy-curable resin is 100° C. or higher.

20. The laminate according to claim 14, wherein the base layer is a polycarbonate film or a film of alicyclic hydrocarbon-based resin.

21. The laminate according to claim 14, wherein the gas barrier layer is an inorganic vapor-deposited film.

22. The laminate according to claim 14, wherein the gas barrier layer is one composed by modifying a surface of a layer containing a polymer compound.

23. The laminate according to claim 14, wherein the energy-curable resin is an ultraviolet ray-curable resin.

24. The laminate according to claim 14, wherein thickness of the layer composed of the cured product of the energy-curable resin is 100 nm or larger.

25. A member for electronic devices composed of the laminate according to a claim 14.

26. An electronic device equipped with the member for electronic devices according to the claim 25.
